(19) United States
(12) Patent Application Publication
(10) Pub. No.: US 2020/0214120 A1
(43) Pub. Date: Jul. 2, 2020

(54) CIRCUIT BOARD HAVING HEAT-DISSIPATION BLOCK AND METHOD OF MANUFACTURING THE SAME

(71) Applicant: Unimicron Technology Corp., Taoyuan (TW)

(72) Inventors: Chin-Sheng WANG, Hsinchu City (TW); Pei-Chang HUANG, Taoyuan (TW)

(21) Appl. No.: 16/283,849

(22) Filed: Feb. 25, 2019

(30) Foreign Application Priority Data
Dec. 27, 2018 (TW) 107147514

(51) Int. Cl. H05K 1/02; H05K 1/18; H05K 3/46; H05K 3/00

(52) U.S. Cl. CPC H05K 1/021; H05K 3/0044; H05K 3/4697; H05K 1/183

(57) ABSTRACT

A method of manufacturing a circuit board having a heat dissipation block includes forming an opening through a substrate to form an open substrate. The opening has a first sidewall and a second sidewall opposite to each other, and the open substrate includes a substrate body surrounding the opening, at least one first fixing portion extending from the substrate body toward the opening and protruding from the first sidewall, and at least one second fixing portion extending from the substrate body toward the opening and protruding from the second sidewall. The heat dissipation block is then clamped between the first fixing portion and second fixing portion to fix the heat dissipation block in the opening.

### CROSS-REFERENCE TO RELATED APPLICATION

This application claims priority to Taiwan Application Serial Number 107147514, filed Dec. 27, 2018, which is herein incorporated by reference.

### BACKGROUND

### Field of Invention

The present disclosure relates to a circuit board having a heat dissipation block and a method of manufacturing the same.

### Description of Related Art

Electronic components (e.g., chips) in a wiring structure generate heat during operation, so a heat dissipation block is usually disposed to conduct the heat generated by the electronic components to outside of the wiring structure. Copper is currently and commonly used as the heat dissipation block due to its ductility and good processability. However, the copper heat dissipation block has a high coefficient of thermal expansion (CTE), which is more susceptible to expansion and deformation when heated, and the difference in degree of thermal expansion between the components may cause a circuit board to warp.

In addition, when the heat dissipation block in the circuit board is made of a material having a low coefficient of thermal expansion and low ductility (e.g., silicon carbide), a method of manufacturing the circuit board having the heat dissipation block is to initially fix the heat dissipation block using an adhesive layer, and then to fill a resin material to fix the heat dissipation block. However, in this method, finally, the adhesive layer needs to be peeled off, and the heat dissipation block is easily displaced during the peeling process.

Therefore, there is a need for a novel method of manufacturing a circuit board having a heat dissipation block to solve the above problems.

### SUMMARY

According to various embodiments of the present disclosure, a method of manufacturing a circuit board having a heat dissipation block is provided, which includes forming an opening through a substrate to form an open substrate. The opening has a first sidewall and a second sidewall opposite to each other, and the open substrate includes a substrate body surrounding the opening, at least one first fixing portion extending from the substrate body toward the opening and protruding from the first sidewall, and at least one second fixing portion extending from the substrate body toward the opening and protruding from the second sidewall. The heat dissipation block is then clamped between the first fixing portion and second fixing portion to fix the heat dissipation block in the opening.

According to some embodiments of the present disclosure, the substrate includes an insulating plate, a metal plate or a wiring board.

According to some embodiments of the present disclosure, the first fixing portion has a first width protruding from the first sidewall, and the second fixing portion has a second width protruding from the second sidewall, in which the first width and the second width are in a range of from about 0.05 mm to about 0.5 mm.

According to some embodiments of the present disclosure, the first fixing portion has at least two first protrusions and at least one first recess, and the first protrusions are in contact with the heat dissipation block, and the at least one first recess is located between the first protrusions and the heat dissipation block, and the second fixing portion has at least two second protrusions and at least one second recess, and the second protrusions are in contact with the heat dissipation block, and the at least one second recess is located between the second protrusions and the heat dissipation block.

According to some embodiments of the present disclosure, the opening further has a third sidewall and a fourth sidewall opposite to each other, and the third sidewall and the fourth sidewall are connected to the first sidewall and the second sidewall, and the open substrate further has at least one third fixing portion and at least one fourth fixing portion, and the third fixing portion extends from the substrate body toward the opening and protrudes from the third sidewall, and the fourth fixing portion extends from the substrate body toward the opening and protrudes from the fourth sidewall, and the third fixing portion and the fourth fixing portion clamp the heat dissipation block.

According to some embodiments of the present disclosure, the third fixing portion has at least two third protrusions and at least one third recess, and the third protrusions are in contact with the heat dissipation block, and the at least one third recess is located between the third protrusions and the heat dissipation block, and the fourth fixing portion has at least two fourth protrusions and at least one fourth recess, and the fourth fixing portions are in contact with the heat dissipation block, and the at least one fourth recess is located between the fourth protrusions and the heat dissipation block.

According to some embodiments of the present disclosure, the third fixing portion has a third width protruding from the third sidewall, and the fourth fixing portion has a fourth width protruding from the fourth sidewall, in which the third width and the fourth width are in a range of from about 0.05 mm to about 0.5 mm.

According to some embodiments of the present disclosure, the heat dissipation block includes a ceramic or a composite material.

According to some embodiments of the present disclosure, the heat dissipation block is selected from one of the group consisting of aluminum silicon carbide (AlSiC), tungsten copper alloy (CuW), tungsten molybdenum alloy (CuMo), silicon carbide (SiC), silicon nitride (AlN), beryllia, chemical vapor deposition diamond (CVD diamond), diamond powder-doped copper, diamond powder-doped aluminum, carbon-based nano-aluminum composite material (CarbAl—N) and carbon-based nano-aluminum composite material (CarbAl-G).

According to various embodiments of the present disclosure, a circuit board having a heat dissipation block is provided, which includes an open substrate and a heat dissipation block. The open substrate includes an opening, a substrate body, at least one first fixing portion and at least one second fixing portion. The opening has a first sidewall and a second sidewall opposite to each other. The substrate body surrounds the opening. The first fixing portion and the second fixing portion extend from the substrate body toward the opening and respectively protrude from the first sidewall and the second sidewall. The heat dissipation block is clamped between the first fixing portion and the second fixing portion.

According to some embodiments of the present disclosure, the first fixing portion has a first width protruding from the first sidewall, and the second fixing portion has a second width protruding from the second sidewall, in which the first width and the second width are in a range of from about 0.05 mm to about 0.5 mm.

According to some embodiments of the present disclosure, the first fixing portion has at least two first protrusions and at least one first recess, and the first protrusions are in contact with the heat dissipation block, and the at least one first recess is located between the first protrusions and the heat dissipation block, and the second fixing portion has at least two second protrusions and at least one second recess, and the second protrusions are in contact with the heat dissipation block, and the at least one second recess is located between the second protrusions and the heat dissipation block.

According to some embodiments of the present disclosure, the opening further has a third sidewall and a fourth sidewall opposite to each other, and the third sidewall and the fourth sidewall are connected to the first sidewall and the second sidewall, and the open substrate further has at least one third fixing portion and at least one fourth fixing portion, and the third fixing portion extends from the substrate body toward the opening and protrudes from the third sidewall, and the fourth fixing portion extends from the substrate body toward the opening and protrudes from the fourth sidewall, and the heat dissipation block is clamped between the third fixing portion and the fourth fixing portion.

According to some embodiments of the present disclosure, the third fixing portion has a third width protruding from the third sidewall, and the fourth fixing portion has a fourth width protruding from the fourth sidewall, in which the third width and the fourth width are in a range of from about 0.05 mm to about 0.5 mm.

According to some embodiments of the present disclosure, the heat dissipation block includes a ceramic or a composite material.

According to some embodiments of the present disclosure, the heat dissipation block is selected from one of the group consisting of aluminum silicon carbide (AlSiC), tungsten copper alloy (CuW), tungsten molybdenum alloy (CuMo), silicon carbide (SiC), silicon nitride (AlN), beryllia, chemical vapor deposition diamond (CVD diamond), diamond powder-doped copper, diamond powder-doped aluminum, carbon-based nano-aluminum composite material (CarbAl—N) and carbon-based nano-aluminum composite material (CarbAl-G).

### BRIEF DESCRIPTION OF THE DRAWINGS

Various aspects of the present disclosure will be fully understood from the following detailed description when reading the accompanying drawings. It is worth noting that various features are not drawn to scale in accordance with standard practice in the industry. In fact, dimensions of the various features may be arbitrarily increased or decreased for clarity of discussion.

FIG. 1 is a flow chart of a method of manufacturing a circuit board having a heat dissipation block according to various embodiments of the present disclosure.

FIGS. 2-8 are top views of a manufacturing method at various stages according to some embodiments of the present disclosure.

FIG. 9 is a top view of a circuit board having a heat dissipation block according to some embodiments of the present disclosure.

FIG. 10 is a cross-sectional view of the circuit board having the heat dissipation block taken along line A-A of FIG. 9.

FIG. 11 is a cross-sectional view of a circuit board having a heat dissipation block according to some embodiments of the present disclosure.

### DETAILED DESCRIPTION

The drawings disclose a plurality of embodiments of the present disclosure below. For the sake of clarity, many practical details will be explained in the following description. However, it should be understood that these practical details are not intended to limit the present disclosure. That is, in some embodiments of the present disclosure, these practical details are not necessary. Moreover, for the sake of simplicity of the drawings, some conventional structures and elements will be illustrated in a simplified schematic manner in the drawings.

In the description, spatially relative terms, such as “beneath,” “below,” “over,” “on,” and the like, may be used herein for ease of description to describe one element or feature's relationship to another element(s) or feature(s) as shown in the figures. The true meaning of the spatially relative terms includes other orientations. For example, when the figure is flipped up and down by 180 degrees, the relationship between one component and another component may change from “beneath” or “below,” to “over” or “on.” In addition, the spatially relative descriptions used herein should be interpreted the same.

Although a series of operations or steps are described below to illustrate the methods disclosed herein, the order of the operations or steps is not to be construed as limiting. For example, certain operations or steps may be performed in a different order and/or concurrently with other steps. In addition, not all illustrated operations, steps and/or features are required to implement embodiments of the present disclosure. Moreover, each of the operations or steps described herein can include a number of sub-steps or actions.

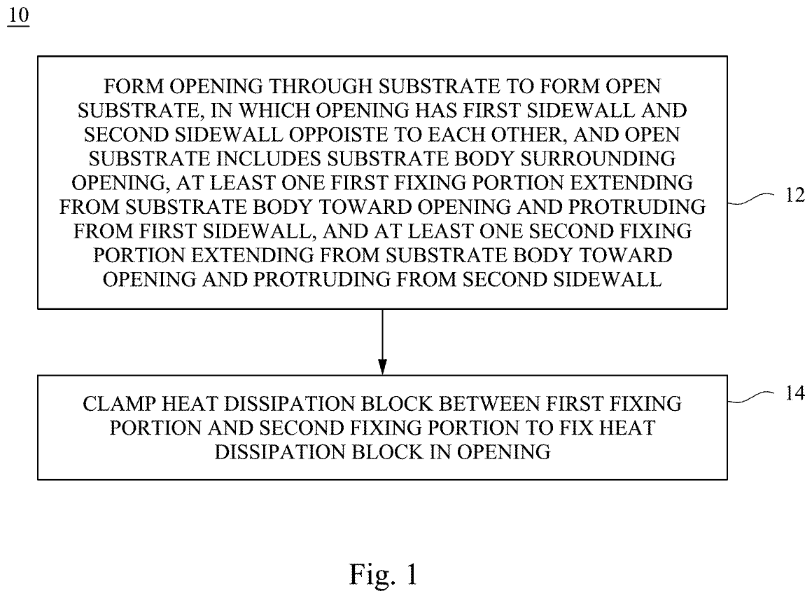

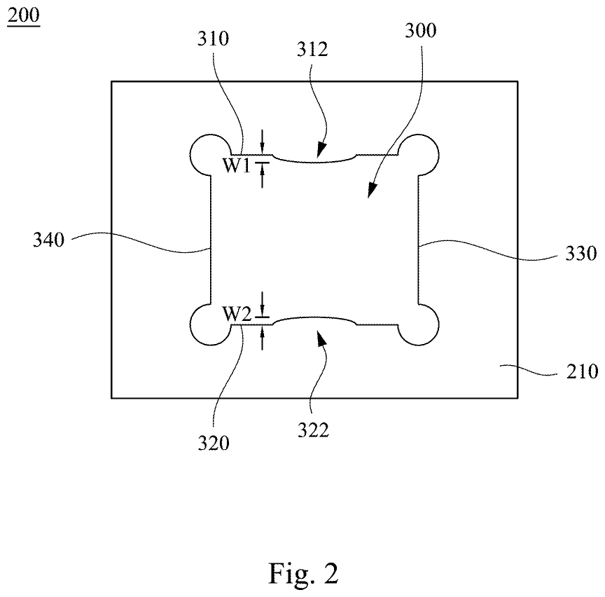

FIG. 1 is a flow chart of a method 10 of manufacturing a circuit board having a heat dissipation block according to various embodiments of the present disclosure. As shown in FIG. 1, the method 10 includes operations 12 and 14. FIGS. 2-8 are top views of a manufacturing method at various stages according to some embodiments of the present disclosure.

Referring to FIGS. 1 and 2, in the operation 12 of the method 10, an opening 300 is formed through a substrate 100 to form an open substrate 200, in which the opening 300 has a first sidewall 310 and a second sidewall 320 opposite to each other. The open substrate 200 includes a substrate body 210 surrounding the opening 300, at least one first fixing portion 312 extending from the substrate body 210 toward the opening 300 and protruding from the first sidewall 310, and at least one second fixing portion 322 extending from the substrate body 210 toward the opening 300 and protruding from the second sidewall 320. In various embodiments, the substrate 100 includes an insulating plate, a metal plate, or a wiring board, but is not limited thereto. In some embodiments, the substrate 100 may be a multi-layered circuit board. In some embodiments, the process of forming the opening 300 may include drilling, laser, routing, punching, or a combination thereof, but is not limited thereto. In some embodiments, the opening 300 may be directly formed using the punching process. In some embodiments, four corners of the opening 300 have an arc-shaped profile recessed toward the substrate body 210, as shown in FIG. 2.

In some embodiments, the first fixing portion 312 has a first width W1 protruding from the first sidewall 310, and the second fixing portion 322 has a second width W2 protruding from the second sidewall 320, and the first width W1 and the second width W2 are in a range of from about 0.05 mm to about 0.5 mm. The protruding first fixing portion 312 and the second fixing portion 322 may be used to fix the heat dissipation block disposed in the opening in subsequent processes.

In some embodiments, the opening 300 further has a third sidewall 330 and a fourth sidewall 340 opposite to each other, and the third sidewall 330 and the fourth sidewall 340 are connected to the first sidewall 310 and the second sidewall 320. It should be noted that although the first fixing portion 312 and the second fixing portion 322 respectively protrude from the longer first sidewall 310 and the second sidewall 320 of the opening 300, the present disclosure is not limited thereto. The first fixing portion 312 and the second fixing portion 322 may be disposed at the shorter third sidewall 330 and the fourth sidewall 340 of the opening 300, respectively.

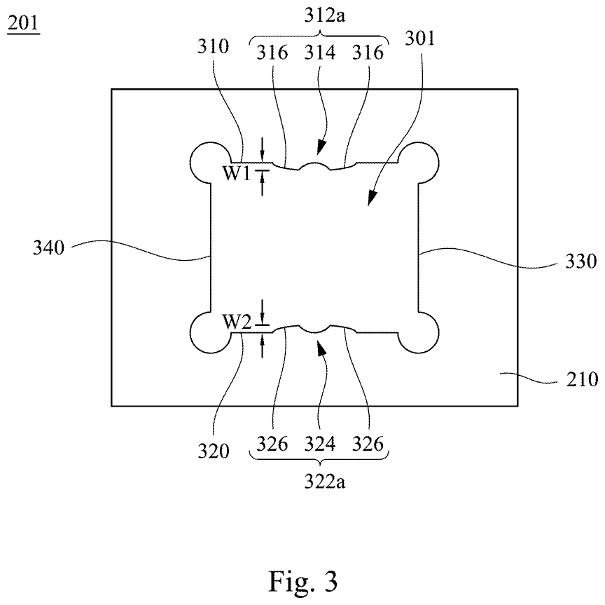

FIGS. 3-7 are top views of open substrates 201, 202, 203, 204, and 205 according to other embodiments of the present disclosure. Firstly, referring to FIG. 3, the difference between the open substrate 201 and the open substrate 200 is that the first fixing portion 312a of the open substrate 201 has at least two first protrusions 316 and at least one first recess 314 located between the first protrusions 316, and the second fixing portion 322a has at least two second protrusions 326 and at least one second recess 324 located between the second protrusions 326. In some embodiments, each of the first protrusions 316 may be aligned with one of the second protrusions 326 to stably fix the heat dissipation block in subsequent processes. In some embodiments, the first recess 314 and the second recess 324 may be formed using a drilling process. In more detail, in some embodiments, the first fixing portion 312 and the second fixing portion 322 shown in FIG. 2 may be respectively drilled to form the first fixing portion 312a and the second fixing portion 322a shown in FIG. 3.

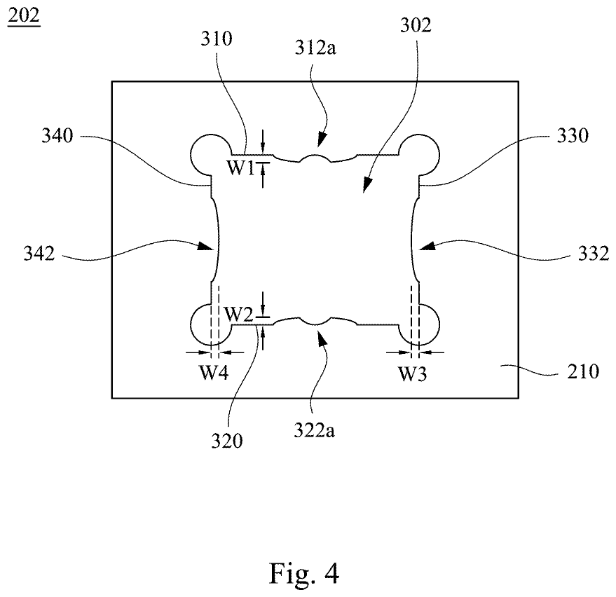

Referring to FIG. 4, the difference between the open substrate 202 and the open substrate 201 is that the open substrate 202 further has at least one third fixing portion 332 and at least one fourth fixing portion 342. The third fixing portion 332 extends from the substrate body 210 of the open substrate 202 toward the opening 302 and protrudes from the third sidewall 330. The fourth fixing portion 342 extends from the substrate body 210 of the open substrate 202 toward the opening 302 and protrudes from the fourth sidewall 340. In some embodiments, the third fixing portion 332 has a third width W3 protruding from the third sidewall 330, and the fourth fixing portion 342 has a fourth width W4 protruding from the fourth sidewall 340, and the third width W3 and the fourth width W4 are in a range of from about 0.05 mm to about 0.5 mm. In some embodiments, the third width W3 and the fourth width W4 may be the same as the first width W1 and the second width W2. In other embodiments, the third width W3 and the fourth width W4 may be different from the first width W1 and the second width W2.

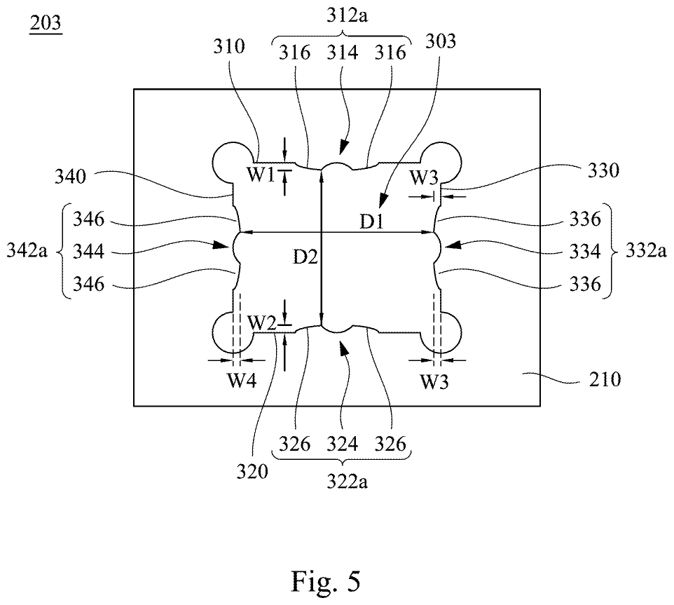

Referring to FIG. 5, the difference between the open substrate 203 and the open substrate 202 is that the third fixing portion 332a of the open substrate 203 has at least two third protrusions 336 and at least one third recess 334 located between the third protrusions 336, and the fourth fixing portion 342a has at least two fourth protrusions 346 and at least one fourth recess 344 located between the fourth protrusions 346. In some embodiments, the third protrusion 336 has a third width W3 protruding from the third sidewall 330, and the fourth protrusion 346 has a fourth width W4 protruding from the fourth sidewall 340, and the third width W3 and the fourth width W4 are in a range of from about 0.05 mm to about 0.5 mm. In some embodiments, the third width W3 and the fourth width W4 may be the same as the first width W1 and the second width W2. In other embodiments, the third width W3 and the fourth width W4 may be different from the first width W1 and the second width W2. The third protrusion 336 and the fourth protrusion 346 may be used to fix the heat dissipation block disposed in the opening together with the first protrusions 316 and the second protrusions 326 in subsequent processes. In some embodiments, each of the first protrusions 316 may be aligned with one of the second protrusions 326, and each of the third protrusions 336 may be aligned with one of the fourth protrusions 346. In some embodiments, there is a distance D2 between the first fixing portion 312a and the second fixing portion 322a, and there is a distance D1 between the third fixing portion 332a and the fourth fixing portion 342a. In some embodiments, the distance D1 and the distance D2 may be the same. In other embodiments, the distance D1 and the distance D2 may be different. The distance D1 and the distance D2 may be selected according to the size of the heat dissipation block to be disposed.

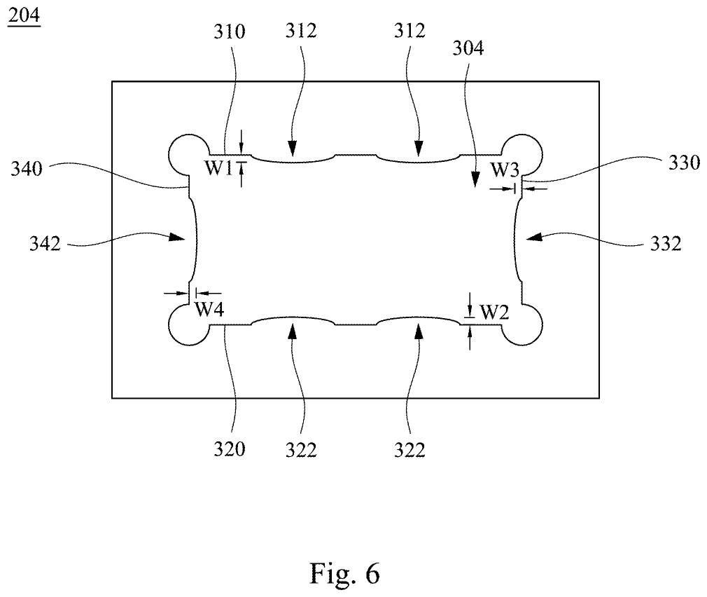

Referring to FIG. 6, the open substrate 204 has a plurality of first fixing portions 312 protruding from the first sidewall 310 of the opening 304, and a plurality of second fixing portions 322 protruding from the second sidewall 320 of the opening 304. In some embodiments, each of the first fixing portions 312 may be aligned with one of the second fixing portions 322, and the position of the third fixing portion 332 can correspond to that of the fourth fixing portion 342. In some embodiments, the width W1 of the first fixing portion 312 and the width W2 of the second fixing portion 322 in the open substrate 204 may be the same as the widths W1 and W2 in the open substrate 200, respectively, and the width W3 of third fixing portion 332 and the width W4 of the fourth fixing portion 342 may be the same as the widths W3 and W4 of the open substrate 202, respectively, and are not described herein again.

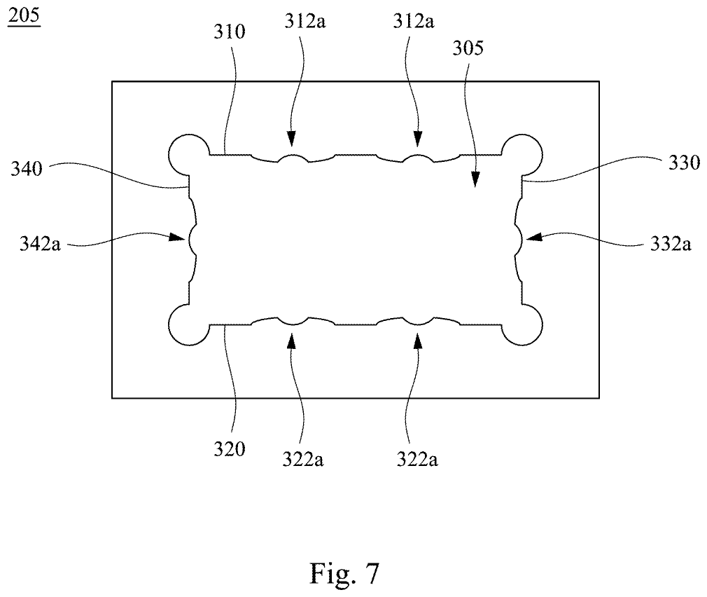

Referring to FIG. 7, the difference between the open substrate 205 and the open substrate 203 is that the open substrate 205 has a plurality of first fixing portions 312a protruding from the first sidewall 310 of the opening 305, and a plurality of second fixing portions 322a protruding from the second sidewall 320 of the opening 305. In some embodiments, each of the first fixing portions 312a may be aligned with one of the second fixing portions 322a, and the position of the third fixing portion 332a may correspond to that of the fourth fixing portion 342a. It should be noted that the number and arrangement of the first fixing portions 312, 312a, the second fixing portions 322, 322a, the third fixing portions 332, 332a, and the fourth fixing portions 342, 342a shown in FIGS. 2-7 are only examples, when the size of the opening is larger, more fixing portions may be arranged to stably fix the heat dissipation block in the opening.

Subsequent steps of the method 10 will be described below by taking the open substrate 203 shown in FIG. 5 as an example.

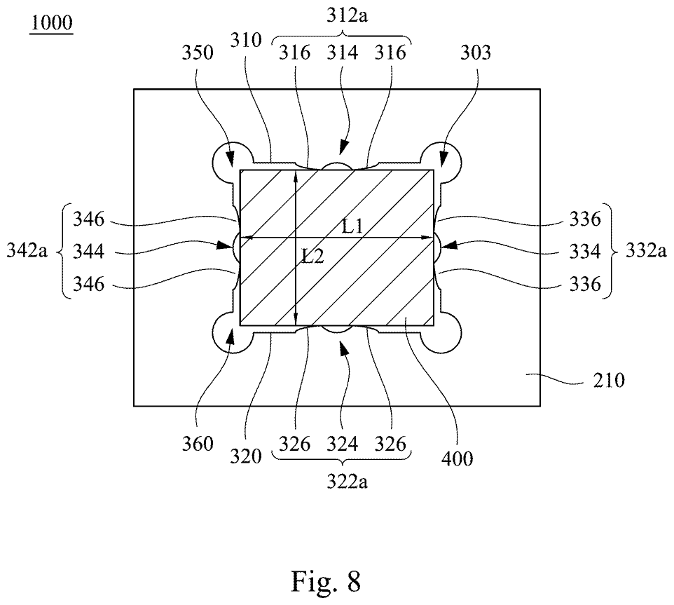

Referring to FIGS. 1 and 8, in the operation 14 of the method 10, the heat dissipation block 400 is clamped between the first fixing portion 312a and the second fixing portion 322a to fix the heat dissipation block 400 in the opening 303, such that the circuit board 1000 having the heat dissipation block is formed. In some embodiments, the first protrusion 316 of the first fixing portion 312a and the second protrusion 326 of the second fixing portion 322a are in contact with and fix the heat dissipation block 400. The first recess 314 may be located between the two first protrusions 316 and the heat dissipation block 400, and the second recess 324 may be located between the two second protrusions 326 and the heat dissipation block 400. As shown in FIG. 8, in some embodiments, when the heat dissipation block 400 is clamped between the first fixing portion 312a and the second fixing portion 322a, a first gap 350 is formed between the heat dissipation block 400 and the first sidewall 310 of the opening 303, and a second gap 360 is formed between the heat dissipation block 400 and the second sidewall 320 of the opening 303.

In various embodiments, the heat dissipation block 400 includes a ceramic or composite material. In some embodiments, the heat dissipation block 400 is selected from one of the group consisting of aluminum silicon carbide (AlSiC), tungsten copper alloy (CuW), tungsten molybdenum alloy (CuMo), silicon carbide (SiC), silicon nitride (AlN), beryllia, chemical vapor deposition diamond (CVD diamond), diamond powder-doped copper, diamond powder-doped aluminum, carbon-based nano-aluminum composite material (CarbAl—N) and carbon-based nano-aluminum composite material (CarbAl-G). In some embodiments, CuW includes 10-20% copper (Cu). In some embodiments, CuMo includes 15-20% molybdenum (Mo). In some embodiments, the heat dissipation block 400 includes aluminum nitride, aluminum carbide, aluminum silicon carbide, or a combination thereof, but is not limited thereto. The heat dissipation block 400 may be other materials having a low coefficient of thermal expansion (e.g., less than 10 ppm/K) and low ductility. In some embodiments, the heat dissipation block 400 may have a metal layer (not shown in FIG. 8) formed using a sputtering and/or plating process on its upper and lower surfaces. The working heat source generated by the electronic components on the circuit board may be transmitted to outside of the circuit board through heat conduction characteristics of the heat dissipation block 400 to maintain working performance of the electronic components and maintain their life. In some embodiments, the heat dissipation block 400 is rectangular-shaped. In some embodiments, the heat dissipation block 400 has a length L2 slightly larger than the distance D2 between the first fixing portion 312a and the second fixing portion 322a (shown in FIG. 5). The heat dissipation block 400 may be fixed in the opening 303 by the length L2 of the heat dissipation block 400 being slightly larger than the distance D2.

In other embodiments, the heat dissipation block 400 may also be clamped between the third fixing portion 332a and the fourth fixing portion 342a. As shown in FIG. 8, the third protrusions 336 of the third fixing portion 332a and the fourth protrusions 346 of the fourth fixing portion 342a are in contact with and fix the heat dissipation block 400. The third recess 334 is located between the two third protrusions 336 and the heat dissipation block 400, and the fourth recess 344 is located between the two fourth protrusions 346 and the heat dissipation block 400. In some embodiments, the heat dissipation block 400 has a length L1 slightly larger than the distance D1 between the third fixing portion 332a and the fourth fixing portion 342a (shown in FIG. 5). The heat dissipation block 400 may be fixed in the opening 303 by the length L1 of the heat dissipation block 400 being slightly larger than the distance D1.

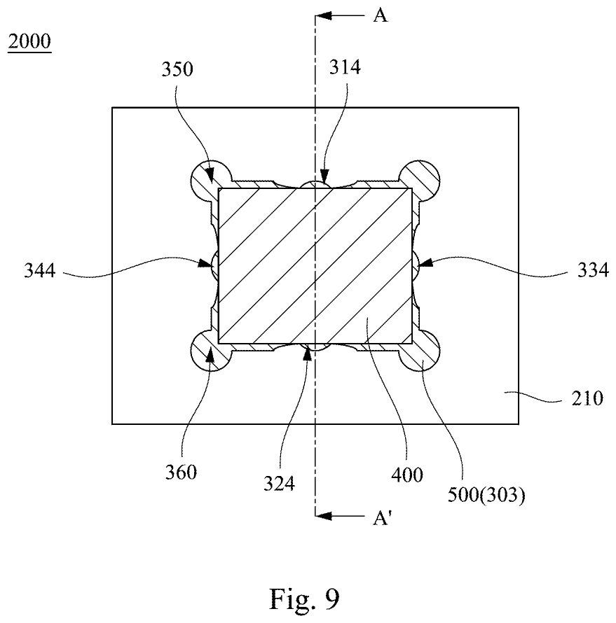

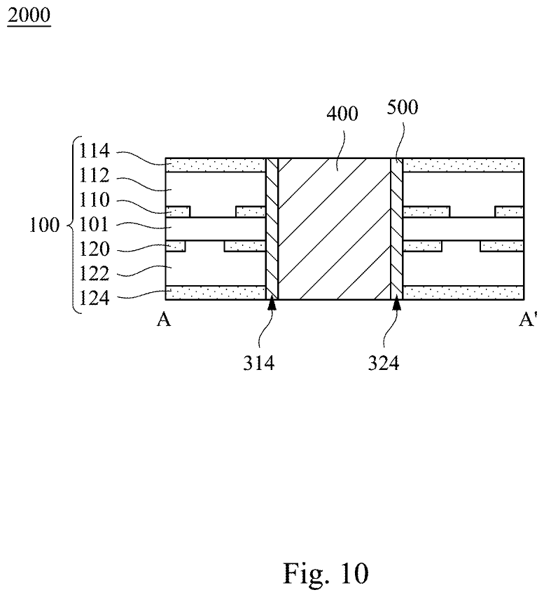

In one embodiment, after the operation 14 is completed, the method 10 may include other operations or steps, as shown in FIGS. 9-10. Firstly, referring to FIG. 9, which is a top view of a process stage after the operation 14 according to some embodiments of the present disclosure. In some embodiments, the method 10 further includes filling a resin material 500 in the first gap 350, the second gap 360, the first recess 314, and the second recess 324. In other embodiments, the method 10 further includes filling the resin material 500 in the third recess 334 and the fourth recess 344. As shown in FIG. 9, after the operation 14, all of the gaps between the heat dissipation block 400 and the open substrate 203 may be filled with the resin material 500, so that the heat dissipation block 400 is fixed in the opening 303 to facilitate subsequent processes performed on the circuit board 2000.

Referring to FIG. 10, which is a cross-sectional view taken along line A-A of FIG. 9. In some embodiments, the circuit board 2000 may be a multi-layered circuit board. For example, the substrate 100 of the circuit board 2000 includes a core plate 101, a first circuit layer 110, a second circuit layer 120, a first dielectric layer 112, a second dielectric layer 122, a first conductive layer 114, and a second conductive layer 124. It should be understood that the structure of the substrate 100 is not limited to that shown in FIG. 10, and the substrate 100 may be any circuit board having a multilayered structure.

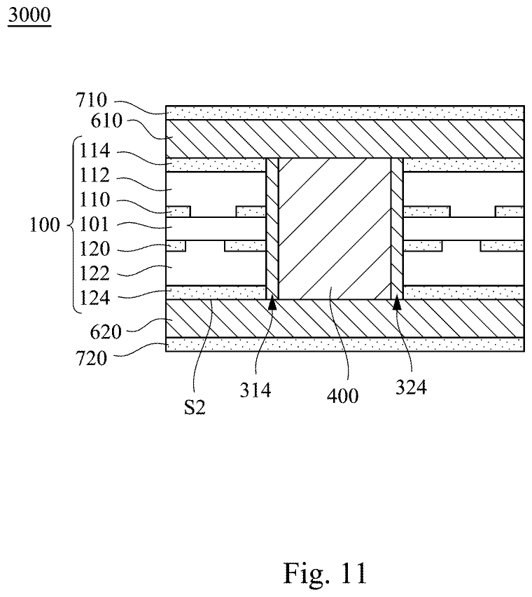

In another embodiment, after the operation 14 is completed, the method 10 further includes forming a third dielectric layer 610 and a fourth dielectric layer 620 over a top surface S1 and a bottom surface S2 of the substrate 100, respectively, forming a third conductive layer 710 over the third dielectric layer 610, and forming a fourth conductive layer 720 beneath the fourth dielectric layer 620, as shown in FIG. 11. FIG. 11 is a cross-sectional view of a process stage after the operation 14 according to other embodiments of the present disclosure. In some embodiments, the third dielectric layer 610 and the fourth dielectric layer 620 may be prepregs or other dielectric materials having fluidity. As shown in FIG. 11, the third dielectric layer 610 and the fourth dielectric layer 620 may be filled in the first recess 314 and the second recess 324. In some embodiments, the third dielectric layer 610 and the fourth dielectric layer 620 may also fill all of the gaps between the heat dissipation block 400 and the open substrate 203 shown in FIG. 8, such as the first gap. 350, the second gap 360, the third recess 334, and the fourth recess 344. In some embodiments, the third conductive layer 710 and the fourth conductive layer 720 may be copper foils.

As described above, according to the embodiments of the present disclosure, the method of manufacturing the circuit board having the heat dissipation block is provided. The heat dissipation block may be directly fixed in the opening by forming the open substrate having the opening with the specific shape and the specific fixing portion structure without using an additional adhesive layer on the bottom of the substrate for fixing the substrate and the heat dissipation block which is subsequent placed in the opening. In addition, the manufacturing method of the present disclosure may selectively fill the gaps between the heat dissipation block and the open substrate with the dielectric material, so that the heat dissipation block may be more firmly fixed in the opening to facilitate subsequent processes performed on the circuit board having the heat dissipation block. Since the heat dissipation block has been fixed by the specific fixing portion structure over the open substrate, the position of the heat dissipation block does not shift during the subsequent processes. Therefore, the method of the present disclosure can improve the problems of the offset heat dissipation block as compared with the prior art method, and can avoid the problems of air bubble residue generated by fixing the heat dissipation block using the adhesive layer. In addition, copper blocks are currently and commonly used as heat dissipation materials, and the heat dissipation blocks in the circuit board are fabricated by relying on ductility and good processability of copper. The method of the present disclosure can use ceramics or other composite materials having low processability as heat dissipation blocks, so that the selection of the heat dissipation materials is more diverse, and the heat dissipation quality of the circuit board may be improved.

The present disclosure has been disclosed in the above embodiments, and is not intended to limit the present disclosure, and it is obvious to those skilled in the art that various alternations and modifications may be made without departing from the spirit and scope of the present disclosure. The scope of the present disclosure is defined by the scope of the appended claims.

1. A method of manufacturing a circuit board having a heat dissipation block, comprising:
forming an opening through a substrate to form an open substrate, wherein the opening has a first sidewall and a second sidewall opposite to each other, and the open substrate comprises:
a substrate body surrounding the opening;
at least one first fixing portion extending from the substrate body toward the opening and protruding from the first sidewall; and
at least one second fixing portion extending from the substrate body toward the opening and protruding from the second sidewall; and
clamping the heat dissipation block between the first fixing portion and the second fixing portion to fix the heat dissipation block in the opening.

2. The method of claim 1, wherein the substrate comprises an insulating plate, a metal plate or a wiring board.

3. The method of claim 1, wherein the first fixing portion has a first width protruding from the first sidewall, and the second fixing portion has a second width protruding from the second sidewall, wherein the first width and the second width are in a range of from about 0.05 mm to about 0.5 mm.

4. The method of claim 1, wherein the first fixing portion has at least two first protrusions and at least one first recess, and the first protrusions are in contact with the heat dissipation block, and the at least one first recess is located between the first protrusions and the heat dissipation block, and the second fixing portion has at least two second protrusions and at least one second recess, and the second protrusions are in contact with the heat dissipation block, and the at least one second recess is located between the second protrusions and the heat dissipation block.

5. The method of claim 1, wherein the opening further has a third sidewall and a fourth sidewall opposite to each other, and the third sidewall and the fourth sidewall are connected to the first sidewall and the second sidewall, and the open substrate further has at least one third fixing portion and at least one fourth fixing portion, and the third fixing portion extends from the substrate body toward the opening and protrudes from the third sidewall, and the fourth fixing portion extends from the substrate body toward the opening and protrudes from the fourth sidewall, and the third fixing portion and the fourth fixing portion clamp the heat dissipation block.

6. The method of claim 5, wherein the third fixing portion has at least two third protrusions and at least one third recess, and the third protrusions are in contact with the heat dissipation block, and the at least one third recess is located between the third protrusions and the heat dissipation block, and the fourth fixing portion has at least two fourth protrusions and at least one fourth recess, and the fourth fixing portions are in contact with the heat dissipation block, and the at least one fourth recess is located between the fourth protrusions and the heat dissipation block.

7. The method of claim 6, wherein the third fixing portion has a third width protruding from the third sidewall, and the fourth fixing portion has a fourth width protruding from the fourth sidewall, wherein the third width and the fourth width are in a range of from about 0.05 mm to about 0.5 mm.

8. The method of claim 1, wherein the heat dissipation block comprises a ceramic or a composite material.

9. The method of claim 1, wherein the heat dissipation block is selected from one of the group consisting of aluminum silicon carbide (AlSiC), tungsten copper alloy (CuW), tungsten molybdenum alloy (CuMo), silicon carbide (SiC), silicon nitride (AlN), beryllia, chemical vapor deposition diamond (CVD diamond), diamond powder-doped copper, diamond powder-doped aluminum, carbon-based nano-aluminum composite material (CarbAl—N) and carbon-based nano-aluminum composite material (CarbAl-G).

10. A circuit board having a heat dissipation block, comprising:
an open substrate, comprising:
an opening, wherein the opening has a first sidewall, a second sidewall opposite to the first sidewall, and round corners at both ends of the first sidewall and the second sidewall;
a substrate body surrounding the opening;
at least one first fixing portion extending from the substrate body toward the opening and protruding from the first sidewall; and
at least one second fixing portion extending from the substrate body toward the opening and protruding from the second sidewall; and
a heat dissipation block clamped between the first fixing portion and the second fixing portion and in direct contact with the first fixing portion and the second fixing portion, wherein the heat dissipation block has a side surface, the entire side surface is substantially flat, and the heat dissipation block comprises a ceramic or a composite material.

11. The circuit board having the heat dissipation block of claim 10, wherein the first fixing portion has a first width protruding from the first sidewall, and the second fixing portion has a second width protruding from the second sidewall, wherein the first width and the second width are in a range of from about 0.05 mm to about 0.5 mm.

12. The circuit board having the heat dissipation block of claim 10, wherein the first fixing portion has at least two first protrusions and at least one first recess, and the first protrusions are in contact with the heat dissipation block, and the at least one first recess is located between the first protrusions and the heat dissipation block, and the second fixing portion has at least two second protrusions and at least one second recess, and the second protrusions are in contact with the heat dissipation block, and the at least one second recess is located between the second protrusions and the heat dissipation block.

13. The circuit board having the heat dissipation block of claim 10, wherein the opening further has a third sidewall and a fourth sidewall opposite to each other, and the third sidewall and the fourth sidewall are connected to the first sidewall and the second sidewall, and the open substrate further has at least one third fixing portion and at least one fourth fixing portion, and the third fixing portion extends from the substrate body toward the opening and protrudes from the third sidewall, and the fourth fixing portion extends from the substrate body toward the opening and protrudes from the fourth sidewall, and the heat dissipation block is clamped between the third fixing portion and the fourth fixing portion.

14. The circuit board having the heat dissipation block of claim 13, wherein the third fixing portion has a third width protruding from the third sidewall, and the fourth fixing portion has a fourth width protruding from the fourth sidewall, wherein the third width and the fourth width are in a range of from about 0.05 mm to about 0.5 mm.

15. (canceled)

16. The circuit board having the heat dissipation block of claim 10, wherein the heat dissipation block is selected from one of the group consisting of aluminum silicon carbide (AlSiC), tungsten copper alloy (CuW), tungsten molybdenum alloy (CuMo), silicon carbide (SiC), silicon nitride (AlN), beryllia, chemical vapor deposition diamond (CVD diamond), diamond powder-doped copper, diamond powder-doped aluminum, carbon-based nano-aluminum composite material (CarbAl—N) and carbon-based nano-aluminum composite material (CarbAl-G).
